(19) United States
(12) Patent Application Publication
(10) Pub. No.: US 2026/0073989 A1
(43) Pub. Date: Mar. 12, 2026

(54) SEMICONDUCTOR STORAGE DEVICE AND CONTROL METHOD THEREOF

(71) Applicant: Kioxia Corporation, Tokyo (JP)

(72) Inventors: Tomoya SANUKI, Yokkaichi (JP); Hitomi TANAKA, Tokyo (JP); Hajime SANO, Tokyo (JP); Reika TANAKA, Yokohama (JP); Tatsuro HITOMI, Yokohama (JP); Yasuhito YOSHIMIZU, Kawasaki (JP)

(73) Assignee: Kioxia Corporation, Tokyo (JP)

(21) Appl. No.: 19/079,782

(22) Filed: Mar. 14, 2025

(30) Foreign Application Priority Data
Sep. 9, 2024 (JP) 2024-155173

(51) Int. Cl. G11C 16/10; G11C 16/04

(52) U.S. Cl. CPC G11C 16/10; G11C 16/0483

(57) ABSTRACT

A semiconductor storage device includes a memory device including a plurality of memory cells, each of the plurality of memory cell including a transistor and configured to store data; and a controller. The controller configured to write data to the plurality of memory cells using a first range from a first voltage to a maximum threshold voltage of the plurality of memory cells, wherein the first voltage is higher than a minimum threshold voltage of the plurality of memory cells by a quarter of an operable range between the minimum threshold voltage and the maximum threshold voltage. The controller configured to heat the plurality of memory cells (i) while writing with the first range, (ii) while reading after the data has been written, or (iii) after the data has been written.

### CROSS-REFERENCE TO RELATED APPLICATION

This application is based upon and claims the benefit of priority from Japanese Patent Application No. 2024-155173, filed Sep. 9, 2024, the entire contents of which are incorporated herein by reference.

### FIELD

Embodiments described herein relate generally to a semiconductor storage device and a control method thereof.

### BACKGROUND

In a NAND flash memory, as the number of cycles of a write operation and an erase operation (hereinafter also referred to as a program/erase (P/E) count) increases, memory characteristics such as a threshold voltage of a memory cell deteriorate.

### DESCRIPTION OF THE DRAWINGS

FIG. 1 is a block diagram showing a configuration example of a memory system according to a first embodiment;

FIG. 2 is a circuit diagram showing a circuit configuration of one block in a memory cell array;

FIG. 3 is a cross-sectional view of a partial region of a block;

FIG. 4 is a cross-sectional view showing a more detailed structure of a memory cell;

FIG. 5 is a graph showing an example of a relationship between a threshold voltage and data of the memory cell;

FIG. 6 is a graph showing a relationship between a P/E count and a shift amount of a threshold voltage of the memory cell;

FIG. 7 is a graph showing a relationship between a P/E count and a variation in a threshold voltage of the memory cell;

FIG. 8 is a graph showing a degree of recovery of a threshold voltage at each voltage state of the memory cell;

FIG. 9 is a graph showing a degree of recovery of a threshold voltage at each voltage state of the memory cell;

FIG. 10 is a graph showing an example of a write state of the memory cell according to the first embodiment;

FIG. 11 is a graph showing a write state of a memory cell according to a first modification example of the first embodiment;

FIG. 12 is a graph showing a write state of a memory cell according to a second modification example of the first embodiment;

FIG. 13 is a cross-sectional view showing a configuration example of a NAND flash memory;

FIG. 14 is a cross-sectional view showing a configuration example of the NAND flash memory;

FIG. 15 is a plan view showing a configuration example of a heater;

FIG. 16 is a flow diagram showing an example of a method of recovering a memory cell according to a second embodiment;

FIG. 17 is a graph showing states of voltage states S3 and S4 adjacent to each other;

FIG. 18 is a graph showing states of voltage states S3 and S4 after annealing;

FIG. 19 shows an example of a correspondence table showing correspondence between the number of defective bits and an annealing temperature; and

FIG. 20 is a graph showing adjacent voltage states written when an annealing temperature is specified.

### DETAILED DESCRIPTION

Embodiments provide a semiconductor storage device and a control method thereof capable of suppressing deterioration of memory characteristics or recovering memory characteristics.

In general, according to one embodiment, a semiconductor storage device includes a memory device including a plurality of memory cells, each of the plurality of memory cell including a transistor and configured to store data; and a controller configured to: write data to the plurality of memory cells using a first range from a first voltage to a maximum threshold voltage of the plurality of memory cells, wherein the first voltage is higher than a minimum threshold voltage of the plurality of memory cells by a quarter of an operable range between the minimum threshold voltage and the maximum threshold voltage; and heat the plurality of memory cells while writing with the first range, while reading data after the data has been written, and/or after the data has been written without an active read or write operation.

Hereinafter, embodiments of the present disclosure will be described with reference to the drawings. The embodiments do not limit the present disclosure. The drawings are schematic or conceptual. In the specification and the drawings, the same elements are given the same reference numerals.

### First Embodiment

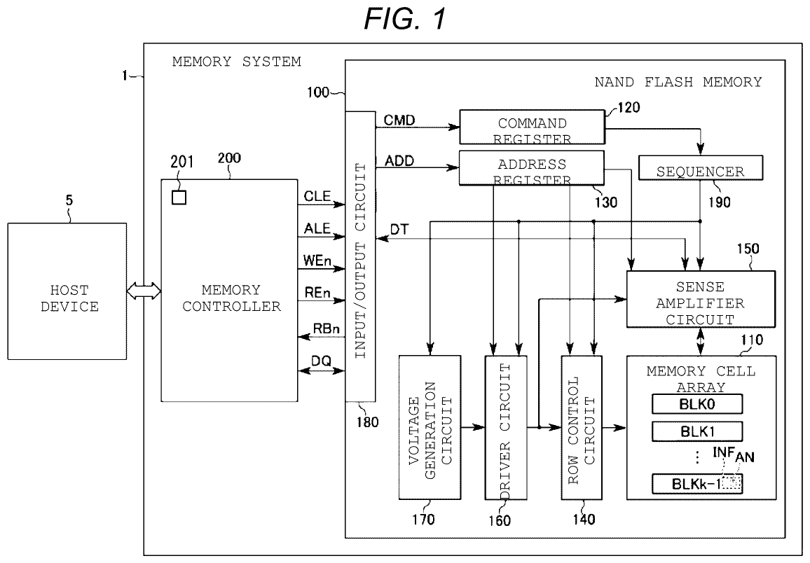

FIG. 1 is a block diagram showing a configuration example of a memory system according to a first embodiment.

A memory system 1 of the present embodiment is connected to a host device 5 via a host bus. The memory system 1 can be requested by the host device 5 to write data, read data, and erase data.

The host device 5 is, for example, a personal computer or a server. The host bus is a bus based on an interface standard such as an SDTM interface, a serial attached small computer system interface (SCSI) (SAS), serial advanced technology attachment (ATA) (SATA), peripheral component interconnect express (PCIe), or non-volatile memory express (NVMe). The memory system 1 may be connected to the host device 5 by wireless communication.

The memory system 1 of the present embodiment includes a NAND flash memory 100 and a memory controller 200. For example, the memory system 1 is a solid state drive (SSD), a memory card, a USB memory, or the like.

The memory controller 200 is electrically coupled to the NAND flash memory 100. The memory controller 200 transmits a command CMD, address information ADD, and a plurality of control signals to the NAND flash memory 100. The NAND flash memory 100 is an example of a memory device according to an embodiment. The NAND flash memory 100 is a non-volatile semiconductor memory device. For example, the NAND flash memory 100 is a collection of a plurality of semiconductor chips. The memory controller 200 includes a storage unit (storage) 201 that stores programs and the like for controlling the NAND flash memory 100.

The NAND flash memory 100 receives the command CMD, the address information ADD, and the plurality of control signals. Data DT is transferred between the NAND flash memory 100 and the memory controller 200. In the following, the data DT transferred from the memory controller 200 to the NAND flash memory 100 during a write sequence is referred to as write data. The write data DT is written into the NAND flash memory 100. During a read sequence, the data DT transferred from the NAND flash memory 100 to the memory controller 200 is referred to as read data. The read data DT is read from the NAND flash memory 100.

The NAND flash memory 100 includes, for example, a memory cell array 110, a command register 120, an address register 130, a row control circuit 140, a sense amplifier circuit 150, a driver circuit 160, a voltage generation circuit 170, an input/output circuit 180, and a sequencer 190.

The memory cell array 110 stores data. A plurality of bit lines and a plurality of word lines are provided in the memory cell array 110. The memory cell array 110 includes a plurality of blocks BLK (BLK0, BLK1, . . . , BLKk-1). k is a natural number equal to or greater than 2. The block BLK is a collection of a plurality of memory cells. Each memory cell is associated with one bit line and one word line. The memory cell array 110 includes a plurality of select gate lines for selecting a unit of controlling in the memory cell array 110.

For example, among the plurality of blocks BLK, a certain number of specific blocks BLK store information INF such as setting information and management information for the operation of the NAND flash memory 100, and information AN regarding state/condition of the NAND flash memory 100. Hereinafter, the information INF is also referred to as ROM information INF. A block BLK that stores the ROM information INF is also referred to as a ROM block.

An internal configuration of the memory cell array 110 will be described later.

The command register 120 stores the command CMD transmitted from the memory controller 200. The command CMD is, for example, a signal including a command for causing the sequencer 190 to execute a read sequence, a write sequence, an erase sequence, and the like.

The address register 130 stores the address information (selected address) ADD transmitted from the memory controller 200. The address information ADD includes, for example, a block address, a page address (word line address), a column address, and the like. The block address, the page address, and the column address are used to select a block BLK, a word line, a select gate line, and a bit line, respectively. Hereinafter, a block selected based on the block address will be referred to as a selected block. A word line selected based on the page address will be referred to as a selected word line.

The row control circuit 140 controls an operation related to rows of the memory cell array 110. The row control circuit 140 selects one block BLK in the memory cell array 110 based on the block address in the address register 130. The row control circuit 140 transfers, for example, a voltage to a selected word line in a selected block, in which the voltage is applied to a wiring corresponding to the selected word line. The row control circuit 140 controls selection and non-selection of a select gate line based on the address information ADD. The row control circuit 140 includes a block decoder, a word line decoder, a select gate line decoder, a switch circuit, and the like.

The sense amplifier circuit 150 controls an operation related to columns of the memory cell array 110. In a write sequence, the sense amplifier circuit 150 applies a voltage to each of the bit lines provided in the memory cell array 110 according to the write data DT from the memory controller 200. In a read sequence, the sense amplifier circuit 150 determines data stored in the memory cells based on whether a current is generated or a fluctuation in a potential of the bit lines. The sense amplifier circuit 150 transfers data based on the determination result to the memory controller 200 as the read data DT. The sense amplifier circuit 150 includes a bit line selection circuit, an amplifier circuit, and the like.

The driver circuit 160 outputs a plurality of voltages used in a read sequence, a write sequence, an erase sequence, and the like to the memory cell array 110. The driver circuit 160 applies a predetermined voltage to wirings corresponding to word lines, bit lines, and the like, based on the address information ADD in the address register 130.

The voltage generation circuit 170 generates a plurality of voltages for various operations of the NAND flash memory 100. The voltage generation circuit 170 outputs the generated voltages to the driver circuit 160.

The input/output circuit 180 functions as an interface circuit on the NAND flash memory 100 side between the NAND flash memory 100 and the memory controller 200. For example, the input/output circuit 180 communicates with the memory controller 200 based on a NAND interface standard such as an open NAND flash interface (ONFi). A command latch enable signal CLE, an address latch enable signal ALE, a write enable signal WEn, a read enable signal REn, a ready busy signal RBn, an input/output signal DQ, and the like are used for communication between the NAND flash memory 100 and the memory controller 200.

The command latch enable signal CLE is a signal indicating that the input/output signal DQ received by the NAND flash memory 100 is the command CMD. The address latch enable signal ALE is a signal indicating that the signal DQ received by the NAND flash memory 100 is the address information ADD. The write enable signal WEn is a signal for instructing the NAND flash memory 100 to input the input/output signal DQ. The read enable signal REn is a signal for instructing the NAND flash memory 100 to output the input/output signal DQ.

The ready/busy signal RBn is a signal for causing the NAND flash memory 100 to notify the memory controller 200 whether the NAND flash memory 100 is in a ready state to receive a command from the memory controller 200 or in a busy state not to receive a command.

The input/output signal DQ is, for example, a signal set having a width of 8 bits. The input/output signal DQ may include the command CMD, the address information ADD, the write/read data DT, and the like.

The sequencer 190 controls the operation of the entire NAND flash memory 100. For example, the sequencer 190 controls each circuit based on the command CMD in the command register 120.

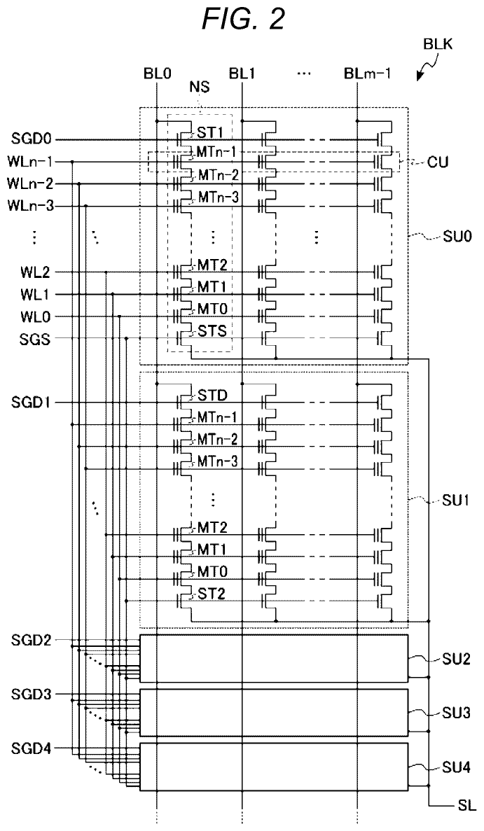

FIG. 2 is a circuit diagram showing a circuit configuration of one block BLK in the memory cell array 110.

One block BLK includes a plurality of (for example, five) string units SU (SU0 to SU4). Each of the string units SU includes a plurality of NAND strings NS. The number of blocks BLK in the memory cell array 110, the number of string units SU in the block BLK, and the number of NAND strings NS in the string unit SU are freely selected.

Each of the NAND strings NS includes a plurality of memory cells MT (MT0 to MTn-1) and select transistors STD and STS. n is a natural number equal to or greater than 2. The plurality of memory cells MT are connected in series between a source of the select transistor STD and a drain of the select transistor STS.

The memory cells MT store data in a substantially non-volatile manner. The memory cell (also referred to as a memory cell transistor) MT is a field-effect transistor that includes a control gate and a charge storage layer.

A gate of the select transistor STD in each of the string units SU0 to SU4 is connected to one corresponding drain-side select gate line among a plurality of drain-side select gate lines SGD0 to SGD4. A gate of the select transistor STS in each of the string units SU0 to SU4 is connected in common to, for example, a source-side select gate line SGS. The gates of the select transistor STS may be connected to different select gate lines SGS for each of the string units SU0 to SU4.

Control gates of the memory cells MT0 to MTn-1 that belong to the same block BLK are connected to one corresponding word line among a plurality of word lines WL (WL0 to WLn-1).

Drains of the select transistors STD of NAND strings NS that belong to the same column in the memory cell array 110 are each connected to one corresponding bit line among a plurality of bit lines BL (BL0 to BL(m-1)). m is a natural number equal to or greater than 2. Sources of a plurality of select transistors STS are connected in common to a source line SL.

The string unit SU is a collection of the NAND strings NS connected to different bit lines BL and the same select gate line SGD. Hereinafter, in each string unit SU, a collection of memory cells MT connected in common to the same word line WL (memory cell group) will also be referred to as a cell unit CU. Data in each cell unit CU is also referred to as a page. The block BLK is a collection of the plurality of string units SU that share the plurality of word lines WL. The memory cell array 110 is a collection of the plurality of blocks BLK that share the plurality of bit lines BL.

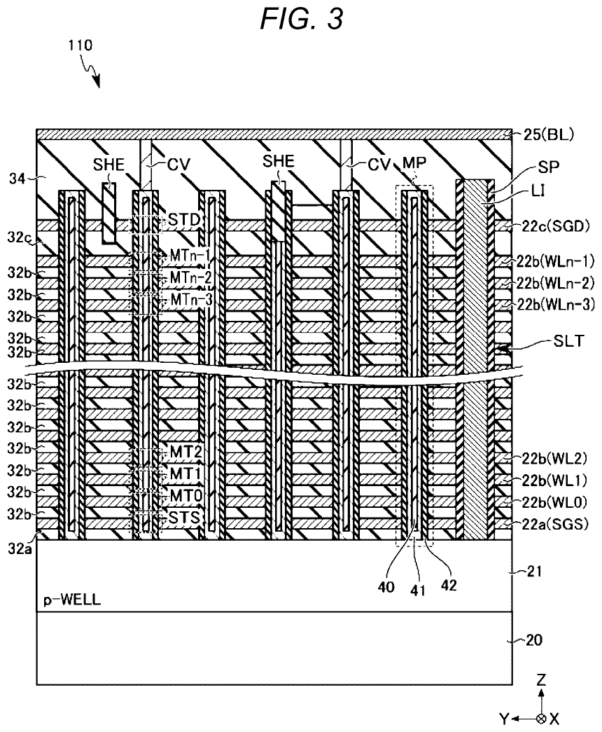

FIG. 3 is a cross-sectional view of a partial region of the block BLK.

In FIG. 3, an X direction corresponds to an extension direction of the word lines WL, a Y direction corresponds to an extension direction of the bit lines BL, and a Z direction corresponds to a direction perpendicular to a surface of a substrate (for example, a semiconductor substrate) 20 used to form the NAND flash memory 100.

As shown in FIG. 3, the memory cell array 110 has a structure (stacked wiring) in which a plurality of conductive layers 22 (22a, 22b, 22c) and a plurality of insulating layers 32 (32a, 32b, 32c) are laminated in the Z direction.

A p-type well region 21 is provided in a semiconductor layer of the semiconductor substrate 20.

The insulating layer 32a is provided on an upper surface of the p-type well region 21. The conductive layer 22a is provided on an upper surface of the insulating layer 32a. The conductive layer 22a is, for example, a plate-shaped layer extending along an X-Y plane configured with the X direction and the Y direction. The conductive layer 22a is used as the select gate line SGS. The conductive layer 22a contains, for example, tungsten.

On an upper surface of the conductive layer 22a, a plurality of insulating layers 32b and a plurality of conductive layers 22b are alternately laminated in the Z direction. The conductive layer 22b is, for example, a plate-shaped layer extending along the X-Y plane. The plurality of laminated conductive layers 22b are used as the word lines WL0 to WLn-1, respectively, in order from the semiconductor substrate 20 side. The conductive layer 22b contains, for example, tungsten.

The conductive layer 22c is provided above the uppermost conductive layer 22b with the insulating layer 32c interposed therebetween. The conductive layer 22c is, for example, a plate-shaped layer extending along the X-Y plane. The conductive layer 22c is used as the select gate line SGD. The conductive layer 22c contains, for example, tungsten.

An insulating layer 34 is provided on an upper surface of the conductive layer 22c. The insulating layer 34 may be configured with a plurality of insulating layers. A conductive layer 25 is provided on an upper surface of the insulating layer 34. The conductive layer 25 is, for example, a line-shaped layer extending in the Y direction. The conductive layer 25 is used as the bit line BL. In a region not shown in the drawing, a plurality of conductive layers 25 are arranged in the X direction. The conductive layer 25 contains, for example, copper.

Each of memory pillars MP extends in the Z direction and is provided in a laminated wiring. The memory pillars MP penetrate the insulating layer 32 and the conductive layer 22. A bottom of the memory pillar MP is in contact with the p-type well region 21. A side surface of the memory pillar MP faces the conductive layer 22. A portion where the memory pillar MP and the conductive layer 22a intersect each other functions as the select transistor STS. A portion where the memory pillar MP and one conductive layer 22b intersect each other functions as one memory cell MT. A portion where the memory pillar MP and the conductive layer 22c intersect each other functions as the select transistor STD.

Each of the memory pillars MP includes, for example, a core member 40, a semiconductor layer 41, and a laminated film 42. The core member 40 is provided to extend in the Z direction. For example, an upper end of the core member 40 is located at a layer higher than the conductive layer 22c. The semiconductor layer 41 is provided between a lower end of the core member 40 and the p-type well region 21. The semiconductor layer 41 covers a periphery of the core member 40. At a lower part of the memory pillar MP, a part of the semiconductor layer 41 is in contact with the p-type well region 21. The laminated film 42 covers a side surface of the semiconductor layer 41. The core member 40 contains, for example, an insulator such as silicon oxide. The semiconductor layer 41 contains, for example, silicon.

A contact CV is provided on an upper surface of the semiconductor layer 41 in the memory pillar MP. In the region shown in the drawing, two contacts CV corresponding to two memory pillars of six memory pillars MP are shown. Among the plurality of memory pillars MP shown in FIG. 3, memory pillars MP that do not overlap a slit SHE and are not connected to the contact CV are connected to the contact CV in the region not shown in the drawing (for example, a region toward a depth direction or a front direction of the paper).

One conductive layer 25 (that is, one bit line BL) is in contact with an upper surface of the contact CV.

A slit SLT has a portion provided along, for example, an X-Z plane, and divides the plurality of conductive layers 22. A contact LI is provided along the slit SLT. A portion of an upper end of the contact LI is in contact with the insulating layer 34. A lower end of the contact LI is in contact with the p-type well region 21. The contact LI is used, for example, as a part of the source line SL. A spacer SP is provided at least between the contact LI and the conductive layer 22. The contact LI is separated and insulated from the conductive layer 22 by the spacer SP.

The slit SHE has a portion that is provided along, for example, the X-Z plane and divides at least the conductive layer 22c. An upper end of the slit SHE is in contact with the insulating layer 34. A lower end of the slit SHE is in contact with the insulating layer 32c between the uppermost conductive layer 22b and the conductive layer 22c. The slit SHE contains an insulator such as silicon oxide.

The above configuration is arranged in a plurality of rows in a depth direction (or a forward direction) of the paper in FIG. 3. The string unit SU is configured by a collection of the plurality of NAND strings NS arranged in the depth direction.

The structure of the memory cell array 110 is not limited to the above-described example, and may have other structures. For example, the memory cell array 110 may be provided above the semiconductor substrate 20 via an insulating layer. Here, elements configuring the row control circuit 140 and the like (for example, field effect transistors) may be provided on the semiconductor substrate 20 below the memory cell array 110.

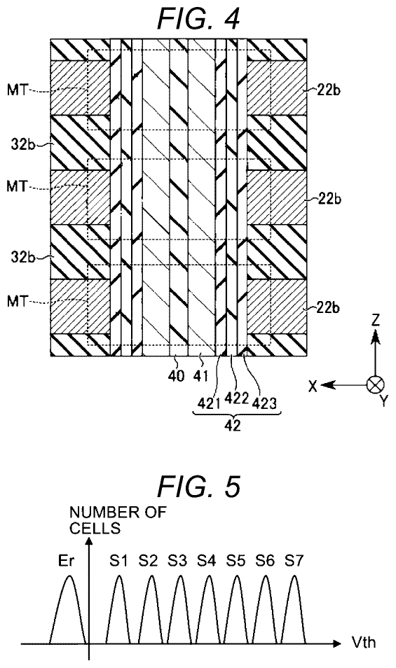

FIG. 4 is a cross-sectional view showing a more detailed structure of the memory cell MT.

As shown in FIG. 4, the laminated film 42 includes a gate insulating film 421, a charge storage layer 422, and a block insulating film 423.

The semiconductor layer 41 functions as a current path for the NAND string NS. The semiconductor layer 41 serves as a region where channels of the memory cell MT and the select transistors STD and STS are formed (hereinafter, referred to as a channel region). The channel region of the memory cell MT faces the conductive layer 22 in a direction parallel to the surface of the semiconductor substrate 20.

The gate insulating film 421 surrounds the side surface of the semiconductor layer 41. The charge storage layer 422 surrounds a side surface of the gate insulating film 421. The block insulating film 423 surrounds a side surface of the charge storage layer 422. The charge storage layer 422 is provided between the gate insulating film 421 and the block insulating film 423.

The gate insulating film 421 functions as a tunnel barrier between the semiconductor layer 41 and the charge storage layer 422. The gate insulating film 421 contains, for example, silicon oxide.

The charge storage layer 422 can store charges injected into the charge storage layer 422 from the semiconductor layer 41 through the gate insulating film 421. The charge storage layer 422 contains, for example, silicon nitride. The charge storage layer 422 may contain silicon.

The block insulating film 423 prevents charges between the charge storage layer 422 and the conductive layer 22 from moving. The block insulating film 423 contains, for example, silicon oxide or aluminum oxide.

In the NAND flash memory 100, when the memory cells MT0 to MTn-1 and the select transistors STD and STS are turned on, a current flows between the bit line BL and the contact LI (source line SL) via the memory pillar MP.

One memory cell MT can store data having number of bits equal to or greater than one by associating a threshold voltage of the memory cell MT with the data to be stored. A memory cell MT that stores one bit of data is referred to as an SLC. A memory cell MT that stores two bits of data is referred to as an MLC. A memory cell MT that stores three bits of data is referred to as a TLC. A memory cell MT that stores four bits of data is referred to as a QLC.

Hereinafter, as an example, the memory cell MT will be assumed as TLC. The present embodiment can be applied to any of SLC, MLC, and QLC.

FIG. 5 is a graph showing an example of a relationship between a threshold voltage Vth and data of a memory cell. The horizontal axis represents a threshold voltage of the memory cell MT. The vertical axis shows the number of memory cells. The memory cell MT can be set to an erased state Er and threshold voltages of voltage states S1 to S7. Thereby, the memory cell MT can store data at eight voltage states, that is, 3-bit data (Er, S1 to S7). The voltage states are threshold voltage levels of memory cells MT corresponding to each piece of data.

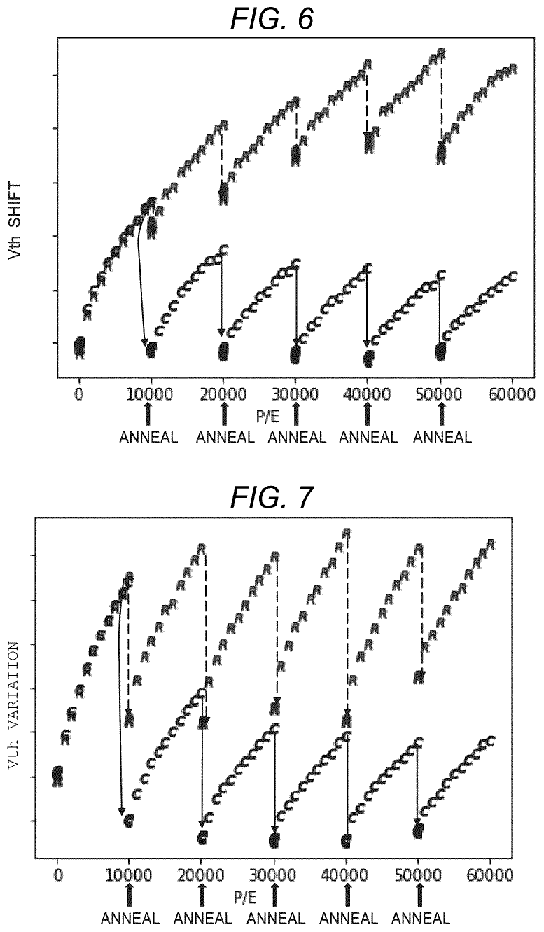

FIG. 6 is a graph showing a relationship between a P/E count and a shift amount of a threshold voltage of a memory cell. The horizontal axis of the graph represents a P/E count of the memory cell MT. The P/E count indicates the number of cycles when writing (Program) and erasing (Erase) of data are repeatedly executed. The vertical axis represents an average shift amount (voltage) in a threshold voltage of the memory cell MT that stores eight pieces of data of TLC.

In FIG. 6, a recovery process is performed by heating (annealing) each time the P/E count reaches 10,000 times, 20,000 times, . . . A temperature condition for annealing will be described later.

In the simulation of the recovery process, after each P/E cycle, data in a memory cell is erased once, and new data at an erase state Er (shown as R in FIG. 6) or a voltage state S3 (shown as C in FIG. 6) is written to the memory cell. Next, annealing is performed while the memory cell is maintained at the erase state Er or the voltage state S3. Next, eight pieces of data of TLC are written to the memory cell, and a threshold voltage of the memory cell in each piece of data (Er, S1 to S7) is compared with a threshold voltage of each piece of data (Er, S1 to S7) in the initial state (before the P/E cycle is performed). Here, a difference in the threshold voltage of each piece of data (Er, S1 to S7) is a shift amount. FIG. 6 shows an average shift amount of threshold voltages in eight pieces of data (Er, S1 to S7) of TLC in the recovery process.

As shown in FIG. 6, a threshold voltage Vth of the memory cell MT to which eight pieces of data of TLC are written rises with an increase in the P/E count with respect to the threshold voltages thereof in the initial state. That is, a shift amount of the threshold voltage Vth increases with an increase in the P/E count. Here, it can be understood that a degree of recovery of data stored in the memory cell during annealing in the case of the erase state Er (shown as R in FIG. 6) is different from that in the case of the voltage state S3 (shown as C in FIG. 6). The erase state Er is a minimum threshold voltage level among the eight states of the threshold voltages of the memory cells MT as shown in FIG. 5. The voltage state S3 is the fourth highest threshold voltage level from the bottom among the eight states of the threshold voltages of the memory cells MT.

For example, when a recovery process is performed when the P/E count is 10,000 times, a threshold voltage when the memory cell MT is annealed while maintaining the erase state Er (R in FIG. 6) drops slightly as indicated by a dashed arrow, and then recovers slightly, but does not return to the same threshold voltage as the original initial state. Meanwhile, a threshold voltage when the memory cell MT is annealed while maintaining the voltage state S3 (C in FIG. 6) recovers to substantially the same threshold voltage as the original initial state as indicated by a solid arrow.

Also in recovery processes that are executed when the P/E count reaches 20,000 times, 30,000 times, and the like, a threshold voltage when the memory cell MT is annealed while maintaining the erase state Er (R in FIG. 6) recovers slightly, but does not return to the original threshold voltage. Meanwhile, a threshold voltage when the memory cell MT is annealed while maintaining the voltage state S3 (C in FIG. 6) recovers to substantially the original threshold voltage in each annealing, regardless of an increase in the P/E count.

FIG. 7 is a graph showing a relationship between a P/E count and a variation in a threshold voltage of a memory cell. The horizontal axis of the graph represents a P/E count of a memory cell MT. The vertical axis represents an average variation in a threshold voltage Vth of the memory cell MT that stores eight pieces of data of TLC.

FIG. 7 also shows the degree of recovery of the memory cell MT when the memory cell MT is annealed while maintaining the erase state Er (shown as R in FIG. 7) and when the memory cell MT is annealed while maintaining the voltage state S3 (shown as C in FIG. 7).

An average variation in the threshold voltage Vth of the memory cell MT to which eight pieces of data of TLC are written increases with an increase in the P/E count.

When the P/E count is 10,000 times and the memory cell MT is annealed while maintaining the erase state Er (R in FIG. 7), an average variation in a threshold voltage decreases and recovers as indicated by a dashed arrow, but does not return to the original state. Meanwhile, when the memory cell MT is annealed while maintaining the voltage state S3 (C in FIG. 7), an average variation in a threshold voltage recovers to substantially the original initial state or to a state better than the original state as indicated by a solid arrow. That is, by annealing the memory cell MT while maintaining the voltage state S3 (C in FIG. 7), an average variation in a threshold voltage is significantly reduced.

Even in annealing that is executed when the P/E count reaches 20,000 times, 30,000 times, . . . , when the memory cell MT is annealed while maintaining the erase state Er (R in FIG. 7), an average variation in a threshold voltage recovers, but does not return to the original state. Meanwhile, when the memory cell MT is annealed while maintaining the voltage state S3 (C in FIG. 7), an average variation in a threshold voltage recovers to the original state or a better state in each annealing, regardless of an increase in the P/E count.

As such, memory characteristics of the memory cell MT can be recovered more satisfactorily when annealing is executed in the state of the voltage state S3 than when annealing is executed in the state of the erase state Er. When in the state of the voltage state S3, the memory cell MT can be recovered to substantially the original memory characteristics by annealing, regardless of the P/E count. The memory characteristics are electrical characteristics of the memory cell MT such as a threshold voltage of the memory cell MT and a variation in the threshold voltage.

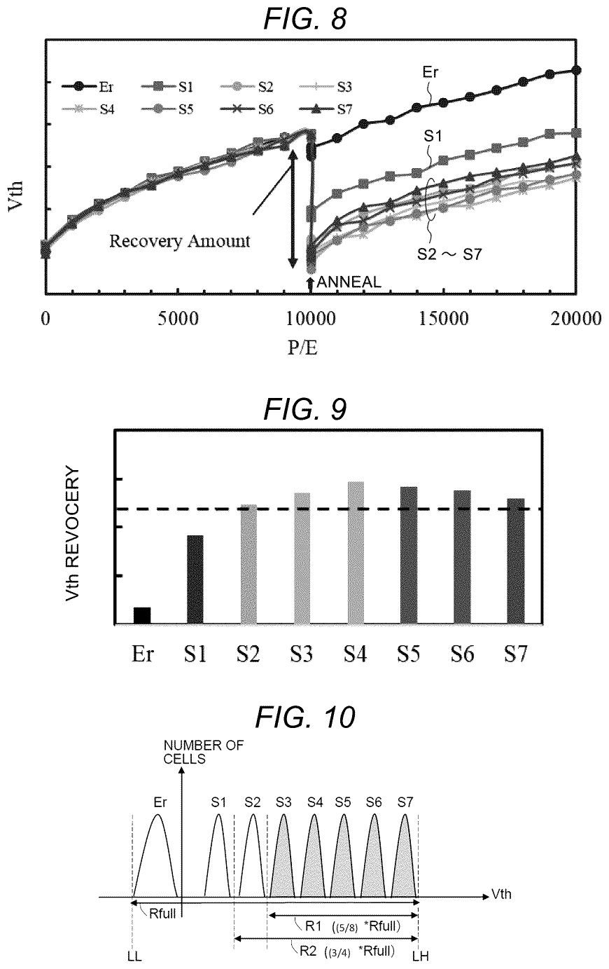

FIG. 8 is a graph showing degrees of recovery of memory cells that store eight pieces of data of TLC when the memory cells are annealed. The horizontal axis represents a P/E count. The vertical axis represents an average shift amount (voltage) in a threshold voltage of the memory cell MT that stores eight pieces of data of TLC.

When the P/E count is 10,000 times, a recovery process by annealing is performed. Here, when the memory cell MT is annealed while maintaining the erase state Er and the voltage state S1, the memory cell MT does not recover sufficiently. Meanwhile, when the memory cell MT is annealed while maintaining the voltage states S2 to S7, the memory cell MT recovers to the original state.

FIG. 9 is a graph showing a degree of recovery of a threshold voltage at each voltage state that is set for a memory cell when annealing is performed. The horizontal axis represents the voltage states Er and S1 to S7 of the memory cell MT when annealing is performed. The vertical axis represents an average recovery amount (voltage) of eight threshold voltages Vth when eight pieces of data of TLC are written to the memory cell MT after annealing. The graph in FIG. 9 also shows that the memory cells MT maintained at the erase state Er and the voltage state S1 during annealing are not fully recovered. Meanwhile, the memory cells MT maintained at the voltage states S2 to S7 during annealing are recovered to the substantially original state. However, since a recovery amount of the voltage state S2 is close to a lower limit, it is preferable to anneal the memory cell MT while the memory cell is maintained at the voltage states S3 to S7.

To recover the memory cell MT maintained at the voltage states S3 to S7, it is preferable that annealing is executed at a temperature of, for example, 85 degrees to 125 degrees. It is understood that the recovery of the memory cell MT maintained at the voltage states S3 to S7 is realized by executing annealing at a temperature equal to or higher than 85 degrees. The NAND flash memory 100 cannot be operated at a temperature higher than 125 degrees due to specifications thereof. Thus, it is preferable that a temperature condition for the annealing be a range of 85 degrees to 125 degrees. Even when a furnace or a heater is not used, the memory cell array 110 can increase the temperature of the memory cell MT to 85 degrees to 125 degrees by repeating cycles of the write operation and the erase operation.

Consequently, during the recovery process, the memory system 1 as a semiconductor storage device according to the present embodiment writes data only at the fourth to eighth voltage states S3 to S7, which have threshold voltages equal to or higher than the voltage state S3, among three bits of the first to eighth voltage states Er and S1 to S7 in an ascending order of the threshold voltage of the memory cell MT. The voltage states Er, S1, and S2 are not used, and data is not written. That is, the plurality of memory cells MT in the memory cell array 110 store data using only the voltage states S3 to S7. The threshold voltage of the memory cell MT in an erased state is also set to be within the range of the voltage states S3 to S7 (R1). Thereby, it is possible to recover the threshold voltage of the memory cell from deterioration due to P/E cycles at temperatures from approximately 85 degrees to approximately 125 degrees.

FIG. 10 is a graph showing an example of a write state of a memory cell according to the first embodiment. The horizontal and vertical axes of the graph may be the same as those in FIG. 5.

The range of a threshold voltage of the memory cell MT that can be used to store data is a range (operable range) Rfull between a minimum threshold voltage LL and a maximum threshold voltage LH. In a normal operation, the memory cell MT can have any threshold voltage in the operable range Rfull.

However, in the present embodiment, in the normal operation, the memory cell MT uses only threshold voltages in a range R1 of voltage states S3 to S7. That is, in the normal operation, the memory controller 200 writes data to a plurality of memory cells MT in the memory cell array 110 only within the range R1 of the voltage states S3 to S7.

In a recovery process of memory characteristics for the memory cells MT, the memory controller 200 heats all or a part of the memory cells MT in the memory cell array 110 at a temperature between 85 degrees and 125 degrees while data is written in the range R1. Thereby, the memory cells MT are heated (annealed) while data is written at threshold voltages in the range R1. That is, the heating process is applied concurrently with the write operation. Additionally, the memory controller 200 can heat the memory cells MT while reading data after the data has been written or after the data has been written without an active read or write operation. That is, the heating process can be performed during a read operation and during idle periods. Heating in any of these conditions facilitates the recovery of memory characteristics of the memory cells MT as described above. As a result, as described above, the memory characteristics of the memory cells MT is satisfactorily recovered.

When the memory controller 200 writes data only in the range R1 to all of the memory cells MT in the memory cell array 110, the memory characteristics of all of the memory cells MT in the memory cell array 110 can be similarly recovered.

In the above embodiment, it is preferable that the memory controller 200 write data within the range R1 of the voltage states S3 to S7. Here, as shown in FIG. 10, the range R1 is a range from a predetermined voltage to the maximum threshold voltage LH, in which the predetermined voltage is higher than the minimum threshold voltage LL by approximately ⅝ of the operable range Rfull.

However, as described with reference to FIGS. 8 to 10, in the normal operation, the memory cell MT can also include the voltage state S2. Here, in the normal operation, the memory controller 200 writes data to the plurality of memory cells MT in the memory cell array 110 within a range R2 of the voltage states S2 to S7 and does not write data with threshold voltages below the range R2. The range R2 is a range from a predetermined voltage to the maximum threshold voltage LH, in which the predetermined voltage is higher than the minimum threshold voltage LL by approximately ¾ of the operable range Rfull. The memory controller 200 anneals the memory cells MT while data is written at threshold voltages within the range R2 as a first range. Even then, as described above, the memory characteristics of the memory cells MT can be satisfactorily recovered.

Since the memory controller 200 writes data only with threshold voltages within the range R1 or R2 of the memory cells MT in the normal operation, only execution of annealing is necessary during the recovery process. The memory controller 200 may execute annealing periodically, for example, once every 24 hours. Alternatively, the memory controller 200 may execute annealing based on the P/E count, for example, once every time the P/E count increases by 10,000 times. When annealing is executed based on the P/E count, the memory controller 200 may execute annealing only for a portion where the P/E count reached a predetermined value. Thereby, it is possible to execute a recovery process for the memory cell MT without interfering a user from usage.

### First Modification Example

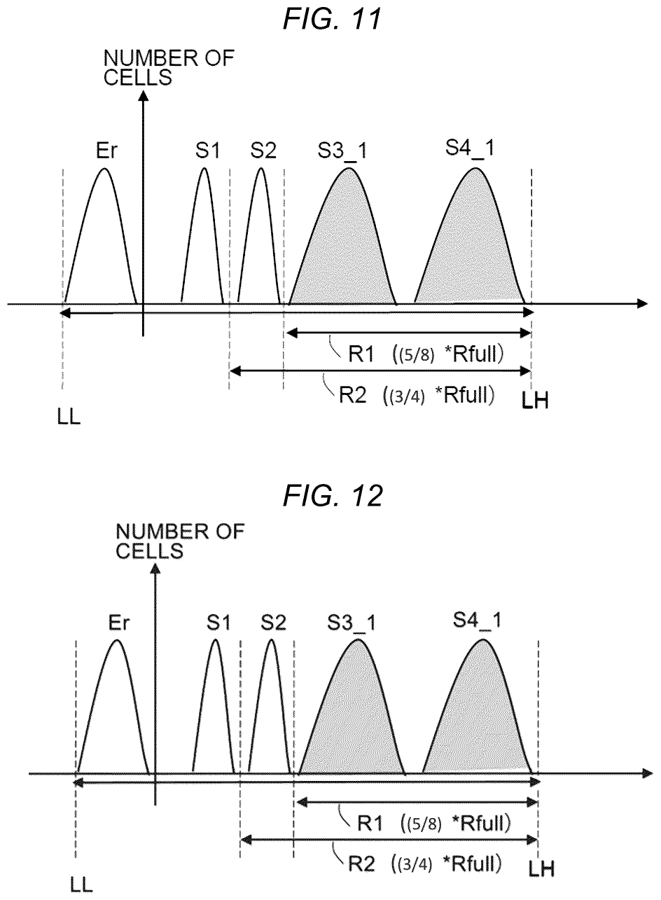

FIG. 11 is a graph showing a write state of a memory cell according to a first modification example of the first embodiment. The horizontal and vertical axes of the graph can be the same as those in FIG. 5.

In the first modification example, the memory controller 200 stores 1-bit data (S3_1, S4_1) in the memory cell MT within the range R1. As such, the memory controller 200 may use the memory cell MT as a single level cell (SLC).

The memory controller 200 may also store 1-bit data in the memory cell MT within the range R2.

### Second Modification Example

FIG. 12 is a graph showing a write state of a memory cell according to a second modification example of the first embodiment. The horizontal and vertical axes of the graph can be the same as those in FIG. 5.

In the second modification example, the memory controller 200 stores 2-bit data (S3_2, S4_2, S5_2, S6_2) in the memory cell MT within the range R1. As such, the memory controller 200 may use the memory cell MT as a multiple level cell (MLC).

The memory controller 200 may also store 2-bit data in the memory cell MT within the range R2.

In the erase operation according to the first embodiment, the memory controller 200 may once lower the threshold voltage of the memory cell MT below the range R1 or R2, and then cause the threshold voltage to transition to a threshold voltage in an erased state within the range R1 or R2. That is, the memory controller 200 may once write data at a voltage state below the range R1 or R2 to the memory cell MT, and then return the voltage state to an erase state within the range R1 or R2. Even then, the range of threshold voltages used in the normal operation will be the range R1 or R2.

Naturally, in the erase operation, the memory controller 200 may cause the threshold voltage of the memory cell MT to directly transition to a threshold voltage in the erased state set within the range R1 or R2 without lowering the threshold voltage of the memory cell MT from the range R1 or R2.

### Heater

In the present embodiment, the memory controller 200 may execute annealing using heat generated when the memory cell array 110 is operated. Meanwhile, a heater HTR may be disposed in the memory cell array 110 to heat the memory cell array 110.

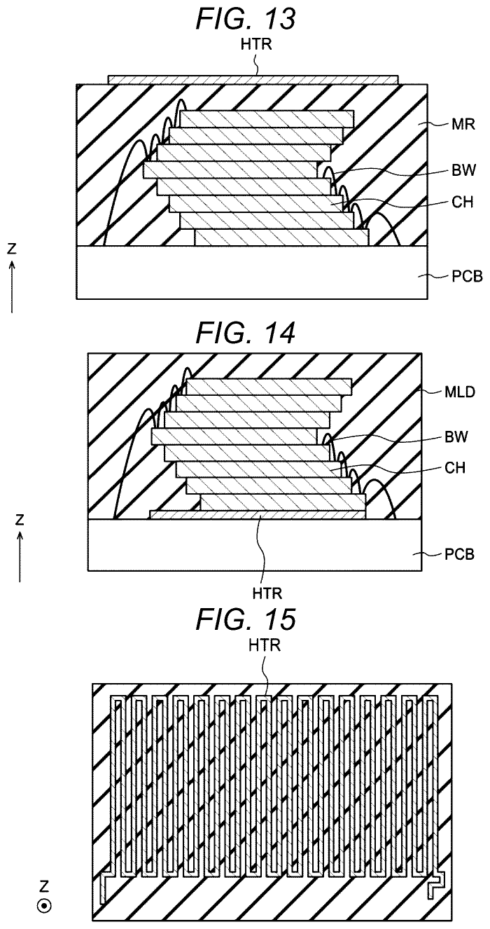

FIGS. 13 and 14 are cross-sectional views showing a configuration example of the NAND flash memory 100. The NAND flash memory 100 includes a wiring board PCB and a plurality of memory chips CH laminated on the wiring board PCB. Wires BW connect the memory chips CH and the wiring board PCB. Resin MR covers the plurality of memory chips CH and the wires BW. In FIG. 13, the heater HTR is disposed on the resin MR. That is, the heater HTR may be disposed outside a package of the memory chips CH. In FIG. 14, the heater HTR is provided between the memory chips CH and the wiring board PCB. That is, the heater HTR may be disposed in the package of the memory chips CH. In the present embodiment, the heater HTR may be provided in either of the arrangements shown in FIGS. 13 and 14. The heater HTR can be controlled to apply heat to the memory cell array 110 during different operational phases. Specifically, the memory controller 200 can activate the heater HTR while writing data to the memory cells MT, while reading data after the data has been written, or after the data has been written without an active read or write operation. The heater HTR can be operated continuously or intermittently based on predefined control logic to facilitate recovery of memory characteristics. Additionally, the heater HTR can provide uniform heating across the memory cell array 110 and/or be configured to selectively heat specific portions of the memory cell array 110. The placement of the heater HTR, whether inside or outside the package of the memory chips CH, can influence the heating efficiency and the extent of thermal recovery achieved.

FIG. 15 is a plan view showing a configuration example of the heater. When the heater HTR shown in FIG. 13 or 14 is viewed in the Z direction, the heater HTR is configured with, for example, a meandering heating wiring as shown in FIG. 15. The heating wiring is configured with a single wiring and generates heat by passing a current from one end to another end. The memory controller 200 may supply power to the heater HTR. Alternatively, an external power source (not shown) may supply power to the heater HTR.

Such the heater HTR may heat the memory cell array 110 during the recovery process for the memory cell MT.

### Second Embodiment

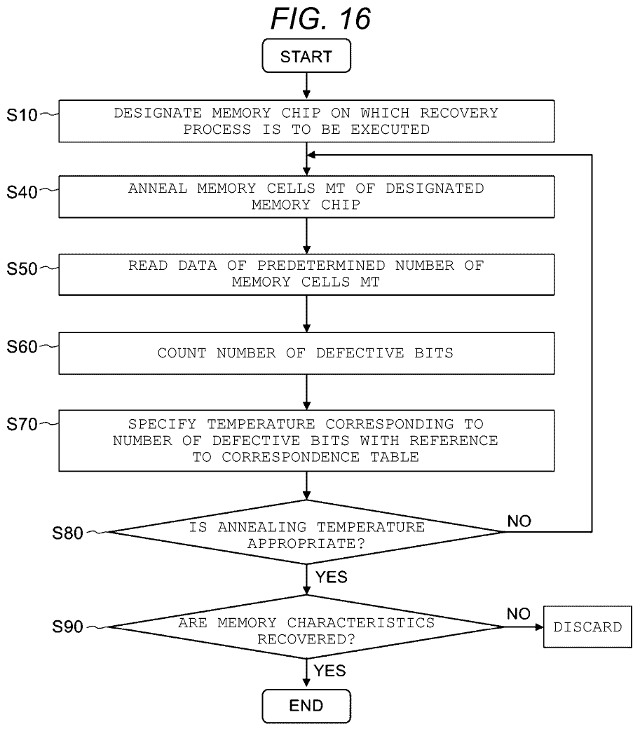

FIG. 16 is a flow diagram showing an example of a recovering method for a memory cell according to a second embodiment.

First, the host device 5 designates a memory chip on which a recovery process is to be executed (S10). An execution timing of the recovery process is determined based on the number of P/E cycles performed on the memory cell, the lapse of a periodically set time, and the like.

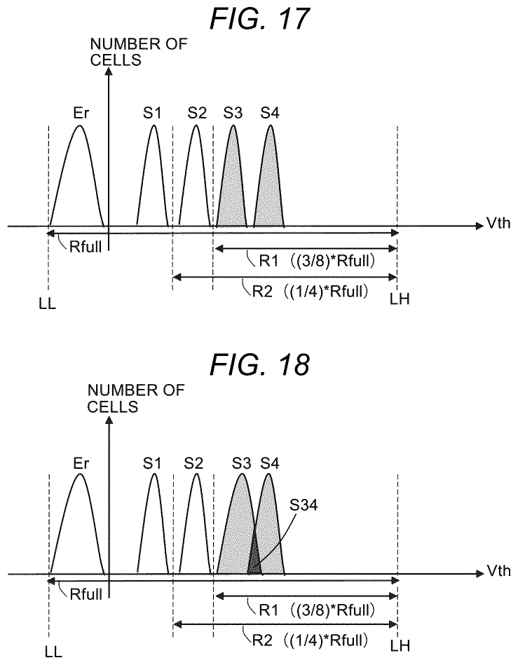

In the second embodiment, the memory controller 200 writes only data of a plurality of adjacent voltage states within the range R1 or R2 to the memory cell MT during the normal operation. For example, FIG. 17 is a graph showing states of adjacent voltage states S3 and S4. Thus, annealing for the recovery process is executed while the data is stored without saving the data to another memory chip.

Next, the memory controller 200 anneals the memory cells MT of the designated memory chip (S40). For example, FIG. 18 is a graph showing states of voltage states S3 and S4 after annealing. By annealing, variations in threshold voltages of the voltage states S3 and S4 increases, and one of the voltage states S3 and S4 may transition to the other voltage state. That is, annealing causes defective bits in the memory cells MT of the target memory chip. The area of S34 in FIG. 18 indicates the number of defective bits (the number of pieces of defective data).

Next, the memory controller 200 reads data of a predetermined number of memory cells MT among the memory cells MT of the target memory chip (S50). Here, the number of pieces of data to be read (number of read bits) is freely selected, and may be the number of pieces of data corresponding to one page or may be the number of pieces of data corresponding to a plurality of pages.

Next, the memory controller 200 counts the number of pieces of defective data (number of defective bits) that transitioned from one of the voltage states S3 and S4 of the read data to the other voltage state (S60). For example, the memory controller 200 counts the number of defective bits shown in S34 of FIG. 18.

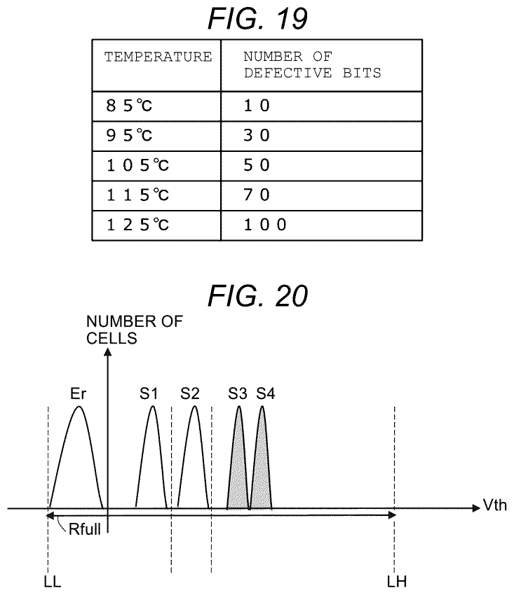

Here, the storage unit 201 shown in FIG. 1 stores a correspondence table showing a relationship between the number of defective bits and the temperature of the memory cell MT in the recovery process. The correspondence table shows a relationship between the temperature and the number of defective bits obtained when the same product is annealed at various temperatures. For example, FIG. 19 is an example of a correspondence table showing correspondence between the number of defective bits and an annealing temperature. In the correspondence table, when the annealing temperature is 85 degrees, the number of defective bits is 10. When the annealing temperature is 90 degrees, the number of defective bits is 30. When the annealing temperature is 105 degrees, the number of defective bits is 50. When the annealing temperature is 115 degrees, the number of defective bits is 70. When the annealing temperature is 125 degrees, the number of defective bits is 100. The memory controller 200 can specify the annealing temperature from the number of defective bits based on such a correspondence between the annealing temperature and the number of defective bits.

The number of pieces of data to be read to count the number of defective bits can be freely selected, but is a predetermined number equal to the number of pieces of data read in step S50. Thereby, the memory controller 200 can accurately specify the temperature from the defective bits based on the correspondence table.

The memory controller 200 specifies a temperature corresponding to the number of defective bits counted in step S60 with reference to the correspondence table stored in the storage unit 201 (S70). Thereby, the memory controller 200 specifies a temperature during annealing the memory cell MT based on the number of defective bits with reference to the correspondence table.

Next, the memory controller 200 determines whether the annealing temperature is appropriate (S80). That is, the memory controller 200 determines whether the annealing temperature specified in step S70 is within the range of 85 degrees to 125 degrees. When the annealing temperature is not within the range of 85 degrees to 125 degrees (NO in S80), steps S40 to S80 are repeated. Here, in step S40, operation and time of the memory cell MT during heating or power to be supplied to the heater HTR is changed and annealing is executed again.

When the annealing temperature is within the range of 85 degrees to 125 degrees (YES in S80), the memory controller 200 writes data to the plurality of memory cells MT subjected to the recovery process and confirms whether memory characteristics are actually recovered (S90).

When the memory characteristics are sufficiently recovered (YES in S90), the memory controller 200 ends the recovery process.

When the memory characteristics are not sufficiently recovered (NO in S90), it means that the memory characteristics are not recovered even when the memory cell MT is annealed at an appropriate temperature. Thus, the memory controller 200 determines that the memory cell MT is damaged and makes the memory cell MT unusable. Alternatively, the memory controller 200 discards the memory chip.

According to the second embodiment, the temperature of the memory cell MT in the memory chip can be specified. Thereby, it is possible to execute annealing in the recovery process at an appropriate temperature. The other configurations and operations in the second embodiment are the same as those in the first embodiment. Thus, in the second embodiment, it is possible to obtain the same effects as those in the first embodiment.

Voltage states (for example, S3, S4) for performing writing in the recovery process may be closer to each other than the voltage states in the normal operation. That is, when the annealing temperature is specified, the memory controller 200 may write data while reducing a difference between adjacent voltage states. Here, the memory controller 200 makes a first voltage difference between adjacent voltage states written in the recovery process smaller than a second voltage difference between adjacent voltage states written in the normal operation. For example, FIG. 20 is a graph showing adjacent voltage states that are written when specifying the annealing temperature. In FIG. 20, the voltage state S3 and the voltage state S4 are made narrower and closer to each other than in a normal write state. Thereby, a write operation is required to specify the annealing temperature in the recovery process, but data stored in the memory cell MT is more likely to transition to the other voltage state (more likely to fail). That is, defective bits are more likely to occur, and the temperature can be specified more finely (with greater sensitivity).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a memory device including a plurality of memory cells, each of the plurality of memory cell including a transistor; and
a controller configured to:
write data to the plurality of memory cells using a first voltage range from a first voltage to a maximum threshold voltage of the plurality of memory cells, wherein the first voltage is higher than a minimum threshold voltage of the plurality of memory cells by a quarter of an operable range between the minimum threshold voltage and the maximum threshold voltage; and
heat the plurality of memory cells (i) while writing the data, (ii) while reading after the data has been written, or (iii) after the data has been written.

2. The semiconductor storage device according to claim 1, wherein the controller is configured to heat the plurality of memory cells at a temperature between 85 degrees and 125 degrees.

3. The semiconductor storage device according to claim 1, wherein the controller is configured to write data at fourth to eighth voltage states among first to eighth voltage states, wherein the first to eighth voltage states correspond to threshold voltage of the memory cells in an ascending order.

4. The semiconductor storage device according to claim 1, wherein the controller is configured to set threshold voltages of the memory cells in a data erased state to be within the first voltage range.

5. The semiconductor storage device according to claim 1, wherein the controller is configured to periodically execute a heating process on the plurality of memory cells.

6. The semiconductor storage device according to claim 1, wherein the controller is configured to operate the plurality of memory cells, which heats the plurality of memory cells.

7. The semiconductor storage device according to claim 1, further comprising a heater provided in the memory device, wherein
the controller is configured to heat the plurality of memory cells using the heater.

8. The semiconductor storage device according to claim 1, wherein the controller is configured to write data at a plurality of adjacent voltage states within the first voltage range to the plurality of memory cells, read data of a predetermined number of memory cells among the plurality of memory cells after heating the plurality of memory cells, count a number of data that transitioned from one voltage state to another voltage state among the read data, and identify a temperature when the plurality of memory cells are heated based on the number of data.

9. The semiconductor storage device according to claim 8, wherein
the controller includes a storage configured to store a table showing a relationship between the number of data and a temperature of the plurality of memory cells, and
the controller is further configured to identify a temperature when the plurality of memory cells are heated from the number of data with reference to the table.

10. A control method for a semiconductor storage device including a plurality of memory cells each including a transistor, and a controller, the control method comprising:
writing data to the plurality of memory cells using a first voltage range from a first voltage to a maximum threshold voltage, wherein the first voltage is higher than a minimum threshold voltage by a quarter of an operable range between the minimum threshold voltage and the maximum threshold voltage; and
heating the plurality of memory cells (i) while writing the data, (ii) while reading after the data has been written, or (iii) after the data has been written.

11. The control method according to claim 10, further comprising heating the plurality of memory cells at a temperature between 85 degrees and 125 degrees.

12. The control method according to claim 10, further comprising writing data at fourth to eighth voltage states among first to eighth voltage states, wherein the first to eighth voltage states correspond to threshold voltage of the memory cells in an ascending order.

13. The control method according to claim 10, further comprising setting threshold voltages of the memory cells in a data erased state to be within the first voltage range.

14. The control method according to claim 10, further comprising periodically executing a heating process on the plurality of memory cells.

15. The control method according to claim 10, comprising operating the plurality of memory cells, which heats the plurality of memory cells.
